(19) United States
(12) Patent Application Publication
(10) Pub. No.: US 2014/0062520 A1
(43) Pub. Date: Mar. 6, 2014

(54) DISPLAY DEVICE AND MOTHER SUBSTRATE

(71) Applicant: SAMSUNG DISPLAY CO., LTD., Yongin-City (KR)

(72) Inventor: Hong-Bo Kim, Yongin-City (KR)

(73) Assignee: SAMSUNG DISPLAY CO., LTD., Yongin -City (KR)

(21) Appl. No.: 13/899,532

(22) Filed: May 21, 2013

(30) Foreign Application Priority Data
Sep. 3, 2012 (KR) 10-2012-0097163

(51) Int. Cl. G09G 3/00

(52) U.S. Cl. CPC G09G 3/006
USPC 324/762.01; 324/537

(57) ABSTRACT

A display device is disclosed. The display device has a display area for displaying images and a non-display area neighboring the display area. The display device includes a test element group (TEG) including a plurality of test pads provided in the non-display area and having different shapes.

### CROSS-REFERENCE TO RELATED APPLICATION

This application claims priority to and the benefit of Korean Patent Application No. 10-2012-0097163 filed in the Korean Intellectual Property Office on Sep. 3, 2012, the entire content of which is incorporated herein by reference.

### BACKGROUND

1. Field

Aspects of embodiments of the present invention relate generally to a display device and a mother substrate.

2. Description of the Related Art

A process for manufacturing a display device may require measurement of factors and quantities such as thickness, resistance, density, degree of contamination, threshold value, and electrical characteristics of an element of the display device (such as a transistor or a capacitor) as a result of each process to determine whether the process produces an acceptable result. However, the measurement process may damage the element, and thus a substrate may not be able to be properly monitored.

In this case, a pattern of a test element group (TEG) is formed in a specific portion of a substrate where elements are formed or in an additional blank area to perform the same process performed on the substrate where the substantial elements are formed. The corresponding process can then be evaluated by allowing a measuring device to contact a plurality of test pads included in the TEG. However, regarding the conventional display device, the test pads included in the TEG have the same shape so it is difficult to intuitively distinguish as to which element each test pad is connected.

The above information disclosed in this Background section is only for enhancement of understanding of the background of the present invention and therefore it may contain information that does not form the prior art that is already known in this country to a person of ordinary skill in the art.

### SUMMARY

Aspects of embodiments of the present invention relate generally to a display device and a mother substrate. More particularly, aspects of embodiments of the present invention relate to a display device including a TEG and a mother substrate including display cells and the TEG. Embodiments of the present invention provide for a display device including a TEG having a plurality of test pads that are intuitively identifiable, and for a mother substrate including display cells and the TEG.

According to an exemplary embodiment of the present invention, a display device is presented. The display device has a display area for displaying an image and a non-display area neighboring the display area. The display device includes a test element group (TEG) including a plurality of test pads in the non-display area and having different shapes.

The TEG may further include a test thin film transistor (TFT) including a test source electrode, a test gate electrode, and a test drain electrode. The test pads may include a first test pad connected to the test source electrode, a second test pad connected to the test gate electrode and having a different shape from the first test pad, and a third test pad connected to the test drain electrode and having a different shape from the first test pad and the second test pad.

Corners of different ones of the test pads may have different shapes.

The different shapes of the corners of the different ones of the test pads may include a right angle shape, a curved shape, and a cut corner shape.

A first one of the test pads may have an oval shape, a second one of the test pads may have a triangular shape, and a third one of the test pads may have a quadrilateral shape.

The display device may further include a display in the display area. The display may include a drive TFT having a gate electrode in a same layer as the test gate electrode, and an organic light emitting element connected to the drive TFT.

The drive TFT may further include a source electrode in a same layer as the test source electrode, and a drain electrode in a same layer as the test drain electrode.

According to another exemplary embodiment of the present invention, a mother substrate is provided. The mother substrate includes a plurality of display cells separated from each other and each having a display area for displaying images and a non-display area neighboring the display area, and a test element group (TEG) including a plurality of test pads outside the display cells and having different shapes.

The test pads may be between neighboring ones of the display cells.

According to the above and other embodiments, a display device including a TEG having a plurality of test pads that are intuitively identifiable, and a mother substrate including display cells and the TEG, are provided.

### BRIEF DESCRIPTION OF THE DRAWINGS

FIG. 1 shows a top plan view of a display device according to a first exemplary embodiment.

FIG. 2 shows a circuit diagram of a pixel of a display shown in FIG. 1.

FIG. 3 shows a top plan view of a TEG shown in FIG. 1.

FIG. 4 shows a top plan view of a TEG of a display device according to a second exemplary embodiment.

FIG. 5 shows a top plan view of a mother substrate according to a third exemplary embodiment.

### DETAILED DESCRIPTION

Hereinafter, the present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention. The drawings and description are to be regarded as illustrative in nature and not restrictive. Like reference numerals designate like elements throughout the specification. Further, in several exemplary embodiments, constituent elements having the same construction are assigned the same reference numerals and are representatively described in connection with a first exemplary embodiment. In the remaining exemplary embodiments, only different constituent elements from those of the first exemplary embodiment are described.

The size and thickness of each component shown in the drawings may be arbitrarily shown (for example, exaggerated) for better understanding and ease of description, but the present invention is not limited thereto. That is, the thicknesses of layers, films, panels, regions, etc., may be exaggerated for clarity. In addition, it will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. It will be understood that when an element such as a layer, file, region, or substrate is referred to as being “on” another element, it can be on the other element or under the other element. In addition, the element may be on the other element with respect to a gravity direction or not on the other element with respect to a gravity direction.

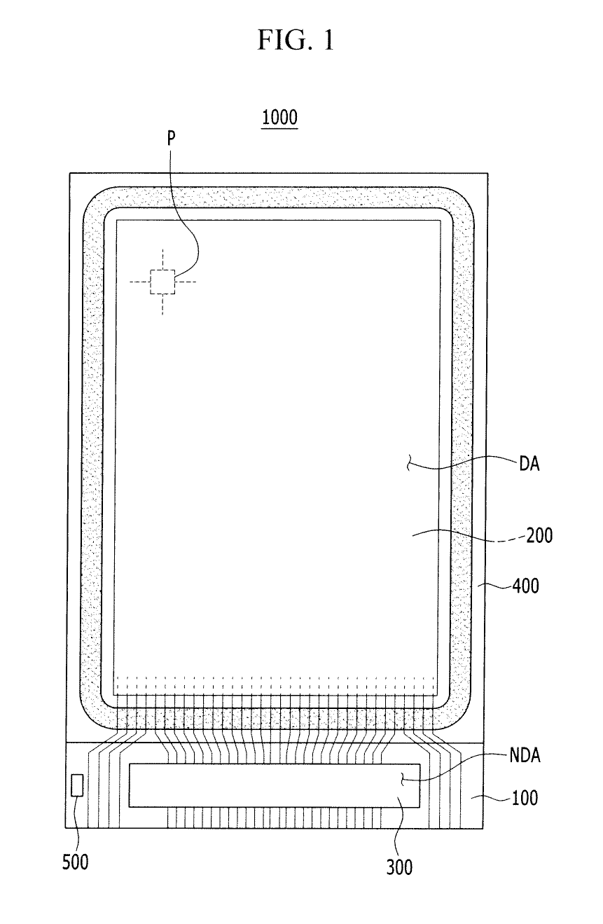

In the accompanying drawings, a two transistor one capacitor (2Tr-1Cap) type active matrix (AM) organic light emitting diode (OLED) display including two thin film transistors (TFTs) and a capacitor for each pixel is shown, but the present invention is not limited thereto. In other embodiments, the OLED display can include at least three TFTs and at least two capacitors for each pixel, and can include an additional wire for various configurations. Here, the pixel represents the minimum unit for displaying an image, and the OLED display displays the image through a plurality of pixels. A display device 1000 according to a first exemplary embodiment will now be described with reference to FIG. 1 to FIG. 3.

FIG. 1 shows a top plan view of the display device 1000.

As shown in FIG. 1, the display device 1000 has a display area DA for displaying an image, and a non-display area NDA neighboring the display area DA. The display device 1000 includes a first substrate 100, a display 200, a driving circuit 300, a second substrate 400, and a TEG 500. The first substrate 100 is made of an inorganic material such as glass, a metal material, or an organic material such as a resin. The first substrate 100 can transmit or block light, and can also be flexible. The display 200 is provided on the first substrate 100. The display 200 is provided in the display area DA on the first substrate 100, and displays the image through a plurality of pixels P. The display area DA and the non-display area NDA are defined by the display 200. Here, the pixel represents the minimum unit for displaying images.

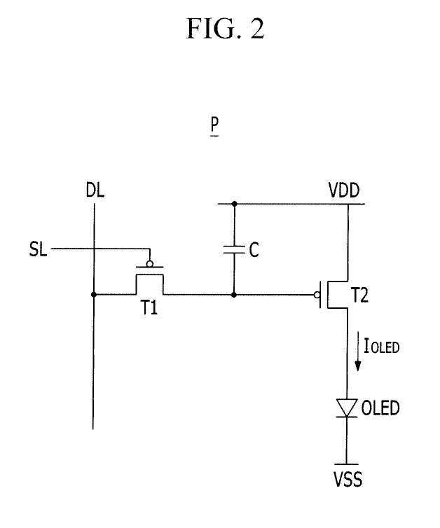

FIG. 2 shows a circuit diagram of one of the pixels P of the display 200 shown in FIG. 1.

As shown in FIG. 2, the pixel P includes at least two drive TFTs T1 and T2, at least one capacitor C, and an organic light emitting element OLED. The drive TFTs include a first TFT T1 and a second TFT T2. The first TFT T1 is connected to a scan line SL and a data line DL, and it transmits a data voltage input by the data line DL to the second TFT T2 according to a switching voltage input to the scan line SL. The capacitor C is connected to the first TFT T1 and a drive power supply line VDD, and it stores a voltage that corresponds to a difference between the voltage transmitted by the first TFT T1 and the voltage that is supplied by the drive power supply line VDD.

The second TFT T2 is connected to the drive power supply line VDD and the capacitor C, and supplies an output current I_{OELD} that is proportional to a square of a difference between the voltage stored in the capacitor C and a threshold voltage of the second TFT T2 to the organic light emitting element OLED. The organic light emitting element OLED emits light according to the current supplied by the output current I_{OELD} and a common power supply line VSS.

Referring to FIG. 1, the driving circuit 300 is provided on the first substrate 100, and neighbors the display 200. For example, the driving circuit 300 is provided at an end of the first substrate 100. The driving circuit 300 is connected to the display 200 and can be connected to a flexible printed circuit board (FPCB). A driving signal for driving the display 200 is supplied to the driving circuit 300 through the flexible printed circuit board, and it is supplied to the display 200 through the driving circuit 300. A driving circuit chip can be installed on the driving circuit 300. Here, the driving signal represents a signal supplied to the display 200 through one or more of the drive power supply line VDD, the common power supply line VSS, the scan line SL, or the data line DL.

The second substrate 400 is provided on the first substrate 100 to face the first substrate 100 with the display 200 therebetween. The second substrate 400 can be made, for example, of an inorganic material such as glass, a metal material, or an organic material such as a resin. The second substrate 400 can transmit or block light, and can also be flexible. The display 200 is covered by the second substrate 400, while the driving circuit 300 and/or the TEG 500 may not be covered by the second substrate 400. The TEG 500 is provided in the non-display area NDA.

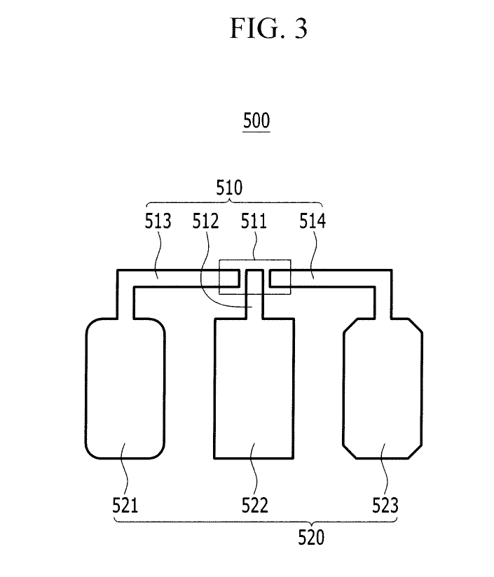

FIG. 3 shows a top plan view of the TEG 500 shown in FIG. 1.

As shown in FIG. 3, the TEG 500 includes a test TFT 510 and a plurality of test pads 520 connected to the test TFT 510. The test TFT 510 may be formed, for example, according to the same process (e.g., at the same time and/or in the same layers) as the drive TFTs T1 and T2 of the display 200. In addition, a plurality of test TFTs 510 can be disposed, for example, in a matrix form. Each test TFT 510 includes a test semiconductor layer 511, a test gate electrode 512 partially overlapping the test semiconductor layer 511 and for transmitting a gate signal, and a test source electrode 513 and a test drain electrode 514 respectively connected to a source region and a drain region of the test semiconductor layer 511.

The test pads 520 include a first test pad 521 connected to the test source electrode 513, a second test pad 522 connected to the test gate electrode 512, and a third test pad 523 connected to the test drain electrode 514. The first test pad 521, the second test pad 522, and the third test pad 523 have different forms (for example, different shapes). For example, in FIG. 3, the test pads 520 have generally rectangular shapes having different corner shapes between the different test pads 520. For instance, the first test pad 521 has curved or rounded (e.g., circular) corners, the second test pad 522 has right angle corners, and the third test pad 523 has cut corner (e.g., octagonal) shapes, in this case with 45° cuts. Each of these corner shapes is different from the others, and they allow a user to intuitively identify one test pad from another of the test pads 520.

While the first test pad 521, the second test pad 522, and the third test pad 523 of FIG. 3 have rectangular shapes having different corner shapes, the present invention is not limited thereto. In another embodiment, for instance, the first test pad, the second test pad, and the third test pad can have a line shape that is bent at least once, with the corners of the first test pad, the second test pad, and the third test pad respectively having a curved (e.g., circular) shape, a straight line (e.g., right angle) shape, and a cut corner shape (e.g., octagonal, such as a 45° cut).

The first test pad 521, the second test pad 522, and the third test pad 523 may be respectively formed with the same material as the test source electrode 513, the test gate electrode 512, and the test drain electrode 514, and may be provided in the same layer, but the present invention is not limited thereto. In other embodiments, the test pads 520 may be formed with different materials from those of the respective electrodes of the test TFT 510, and may be provided in different layers from these electrodes as well.

A probe for measuring a characteristic of the test TFT 510 can contact the first test pad 521, the second test pad 522, and the third test pad 523. Further, a gate signal can be applied to the second test pad 522 by using the probe, while an electrical characteristic of the test TFT 510 can be checked by measuring a data signal flowing between the first test pad 521 and the third test pad 523. As such, electric characteristics of the drive TFTs T1 and T2 included in the display 200 can be checked.

A plurality of test pads 520 of the display device 1000 are connected to the test TFT 510. In another embodiment, a plurality of test pads of a display device can be connected to another circuit, such as a test capacitor.

As described, regarding the display device 1000, the first test pad 521, the second test pad 522, and the third test pad 523 have different shapes so that when a testing user has the probe contact the first test pad 521, the second test pad 522, and the third test pad 523, the user can intuitively identify whether the probe, as connected to the first test pad 521, the second test pad 522, and the third test pad 523, is respectively connected to the test source electrode 513, the test gate electrode 512, and the test drain electrode 514.

Therefore, when testing the TEG 500, the positions where the probe contacts the test pads 520 can be immediately identified so that the test can be quickly and accurately performed. In addition, when the respective shapes of the test pads 520 are set according to a common rule, the display device 1000 can allow free communication between the designer of the TEG 500 and the user of the TEG 500. Accordingly, through the configuration of the TEG 500, the user of the TEG 500 can distinguish the test pads 520 included in the TEG 500 without additional training.

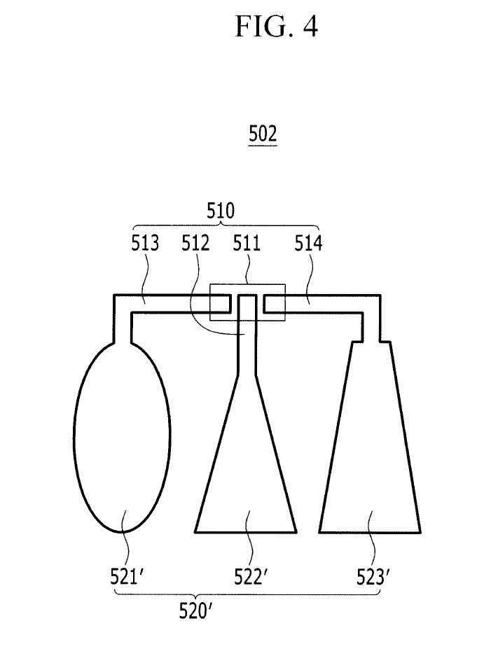

A TEG 502 of a display device according to a second exemplary embodiment will now be described with reference to FIG. 4. Parts that different from the first exemplary embodiment will be described, and parts that are not described will follow the first exemplary embodiment. For better comprehension and ease of description, the same constituent elements of the second exemplary embodiment as in the first exemplary embodiment have the same reference numerals.

FIG. 4 shows a top plan view of the TEG 502 of a display device (for example, a display device similar to the display device 1000 of FIG. 1).

As shown in FIG. 4, a plurality of test pads 520′ of the TEG 502 of a display device include a first test pad 521′ connected to the test source electrode 513, a second test pad 522′ connected to the test gate electrode 512, and a third test pad 523′ connected to the test drain electrode 514. The first test pad 521′, the second test pad 522′, and the third test pad 523′ have different shapes from each other. As shown in FIG. 4, the first test pad 521′ has an oval shape, the second test pad 522′ has a triangular shape, and the third test pad 523′ has a quadrilateral shape (in this case, a trapezoidal shape).

The first test pad 521′, the second test pad 522′, and the third test pad 523′ can be made of the same materials as the test source electrode 513, the test gate electrode 512, and the test drain electrode 514, and can be provided in the same layer as their respective electrodes. In other embodiments, the test pads 520′ can be made of different materials from their respective electrodes of the test TFT 510, and can be provided in different layers from these respective electrodes.

As described, regarding a display device having the TEG 502, the first test pad 521′, the second test pad 522′, and the third test pad 523′ have different shapes so that when a testing person has a probe contact the first test pad 521′, the second test pad 522′, and the third test pad 523′, the person can intuitively identify that the probe, as connected to first test pad 521′, the second test pad 522′, and the third test pad 523′, is connected to the test source electrode 513, the test gate electrode 512, and the test drain electrode 514, respectively. Therefore, when the user tests the TEG 502 in a display device, the positions where the probe contacts can be immediately identified so the test can be performed quickly and accurately.

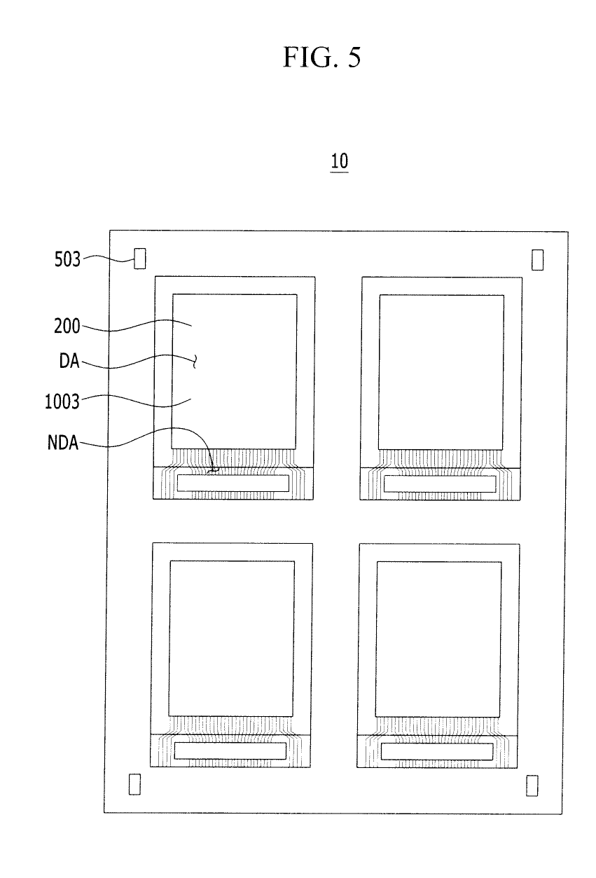

A mother substrate 10 according to a third exemplary embodiment will now be described with reference to FIG. 5. Parts that are different from the first exemplary embodiment or the second exemplary embodiment will be selected and described, and parts that are not described will follow the first exemplary embodiment or the second exemplary embodiment. For better comprehension and ease of description, the same constituent elements of the third exemplary embodiment as the first exemplary embodiment or the second exemplary embodiment have the same reference numerals.

FIG. 5 shows a top plan view of the mother substrate 10.

As shown in FIG. 5, the mother substrate 10 includes a plurality of display cells 1003 separated from each other. Each of the display cells 1003 has a display area DA for displaying images and a non-display area NDA neighboring the display area DA. Each of the display cells 1003 includes a display 200, and each such display cell 1003 can be formed as a display device similar to the display device 1000 when cut from the mother substrate 10.

At least one TEG 503 is provided on the mother substrate 10 outside of the display cells 1003, such as between neighboring display cells 1003 or, as shown in FIG. 5, at different corners of the mother substrate 10. The TEG 503 is provided outside the display cells 1003 that are cut from the mother substrate 10 to function as separate display devices. The TEG 503 includes a plurality of test pads that have different shapes. For example, the test pads can have the same shapes as the test pads 520 included in the display device 1000 described above, or the same shapes as the test pads 520′ of a display device described above, or still different shapes representative of other embodiments of the present invention. The testing person can detect the electrical characteristics of the drive TFT included in the display 200 of the display cell 1003 before cutting the display cell 1003 from the mother substrate 10 by using the TEG 503.

As described, regarding the mother substrate 10, the TEG 503 is provided outside the display cells 1003 or between the neighboring display cells 1003 to be cut from the mother substrate 10 so that the electrical characteristics of the drive TFT included in the display 200 of the display cells 1003 can be tested by using the TEG 503 before the display cells 1003 are cut from the mother substrate 10. The test pads included in the TEG 503 have different shapes so a testing person can intuitively distinguish the test pads when contacting a probe to the test pads. Hence, in the mother substrate 10, the positions to contact the probe can be instantly checked and the TEG 503 can be quickly and accurately tested.

While the present invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and their equivalents.

What is claimed is:

1. A display device having a display area for displaying an image and a non-display area neighboring the display area, the display device comprising:
a test element group (TEG) comprising a plurality of test pads in the non-display area and having different shapes.

2. The display device of claim 1, wherein:
the TEG further includes a test thin film transistor (TFT) including a test source electrode, a test gate electrode, and a test drain electrode; and
the test pads comprise:
a first test pad connected to the test source electrode;
a second test pad connected to the test gate electrode and having a different shape from the first test pad; and
a third test pad connected to the test drain electrode and having a different shape from the first test pad and the second test pad.

3. The display device of claim 2, wherein corners of different ones of the test pads have different shapes.

4. The display device of claim 3, wherein the different shapes of the corners of the different ones of the test pads include a right angle shape, a curved shape, and a cut corner shape.

5. The display device of claim 2, wherein a first one of the test pads has an oval shape, a second one of the test pads has a triangular shape, and a third one of the test pads has a quadrilateral shape.

6. The display device of claim 2, further comprising a display in the display area, the display comprising:
a drive TFT having a gate electrode in a same layer as the test gate electrode; and
an organic light emitting element connected to the drive TFT.

7. The display device of claim 6, wherein the drive TFT further comprises:
a source electrode in a same layer as the test source electrode; and
a drain electrode in a same layer as the test drain electrode.

8. A mother substrate comprising:
a plurality of display cells separated from each other and each having a display area for displaying images and a non-display area neighboring the display area; and
a test element group (TEG) comprising a plurality of test pads outside the display cells and having different shapes.

9. The mother substrate of claim 8, wherein the test pads are between neighboring ones of the display cells.
